(19) United States
(12) Patent Application Publication
(10) Pub. No.: US 2007/0153451 A1
(43) Pub. Date: Jul. 5, 2007

(54) MOUNTING APPARATUS FOR COMPUTER POWER SUPPLY

(75) Inventors: Yun-Lung Chen, Tu-Cheng (TW); Jun Tang, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/306,459

(22) Filed: Dec. 29, 2005

(51) Int. Cl. H05K 5/00

(52) U.S. Cl. 361/679

(57) ABSTRACT

A mounting apparatus is used for securing an electronic device (50) to a computer enclosure. The mounting apparatus includes a chassis (60), a bracket (10), and a retention member (30). The chassis includes a bottom panel (80). The bracket is secured on the bottom panel of the chassis. The bracket includes a first side wall (14) and a second side wall (16) for cooperatively sandwiching the electronic device therebetween. The retention member pivotably attached to the chassis and engaged with one of the first and second side walls to lock the electronic device between the first and second side walls.

### FIELD OF THE INVENTION

The present invention relates to mounting apparatus, and more particularly to a mounting apparatus for conveniently securing a computer power supply in a computer enclosure.

### DESCRIPTION OF RELATED ART

A conventional computer system usually includes a power supply in a chassis. The installation of the power supply in the chassis usually involves the use of screws.

A computer enclosure for mounting power supplies is provided. The computer enclosure includes a rear panel, a fixing bracket attached to the rear panel, and a bridge, which attaches to the fixing bracket. The rear panel defines an opening therein. The fixing bracket includes first and second side walls opposite each other to define a receiving space therebetween in communication with the opening in the rear panel adapted for receiving a power supply therein. The bridge includes first and second ends respectively connected to the first and second side walls of the fixing bracket for positioning and fastening the power supply. The bridge is secured to the fixing bracket by screws.

However, it is inconvenient to use the screws to secure the power supply in the chassis of the computer. The screws are small and make them difficult to manipulate and install. Additionally, because of their small size, the screws may be dropped by an assembler, possibly causing damage to other parts of the computer system due to shorts, lodging in moving parts, and the like.

What is needed, therefore, is a mounting apparatus, which allows convenient securing of a power supply in a computer enclosure.

### SUMMARY OF INVENTION

A mounting apparatus is used for securing an electronic device to a computer enclosure. The mounting apparatus includes a chassis, a bracket, and a retention member. The chassis includes a bottom panel. The bracket is secured on the bottom panel of the chassis. The bracket includes a first side wall and a second side wall for cooperatively sandwiching the electronic device therebetween. The retention member pivotably attached to the chassis and engaged with one of the first and second side walls to lock the electronic device between the first and second side walls.

Other advantages and novel features will be drawn from the following detailed description of a preferred embodiment with attached drawings, in which:

### BRIEF DESCRIPTION OF DRAWINGS

FIG. 1 is an exploded, isometric view of a mounting apparatus for a computer power supply of a preferred embodiment of the present invention, the mounting apparatus comprises a bracket and a retention member;

FIG. 2 is an exploded, isometric view of the power supply and the bracket of FIG. 1, but viewed from another aspect;

FIG. 3 is an assembled, isometric view of the mounting apparatus for the power supply in a chassis, showing the mounting apparatus in a locked position;

FIG. 4 is similar to FIG. 3, but showing the mounting apparatus in a unlocked position.

FIG. 5 is an exploded, isometric view of a mounting apparatus for a computer power supply of another preferred embodiment of the present invention;

FIG. 6 is an assembled, isometric view of FIG. 5, showing the mounting apparatus in a unlocked position.

### DETAILED DESCRIPTION

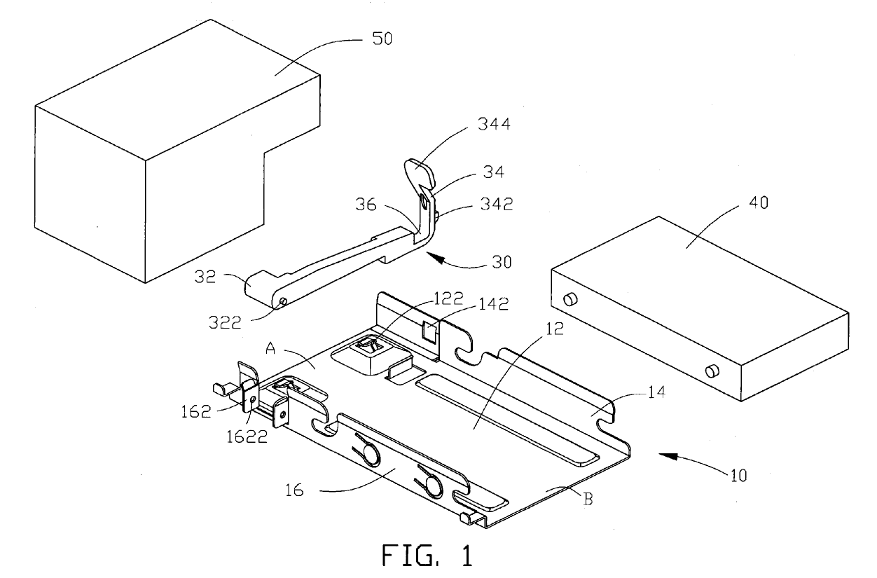

Referring to FIG. 1, a mounting apparatus for a computer power supply 50 comprises a bracket 10, and a retention member 30. The retention member 30 secures the power supply 50 in a computer chassis.

The bracket 10 includes a bottom wall 12, and a first side wall 14 and a second side wall 16 respectively bent from opposite edges of the bottom wall 12. Two locking clips 122 are formed on the bottom wall 12. A retaining portion 142 is defined in the first side wall 14. A pair of retaining clips 162 is bent out from the second side wall 16. A pair of pivot holes 1622 is respectively defined in the retaining clips 162. The bracket 10 is divided into area A and area B. The locking clips 122, the retaining portion 142, and the retaining clips 162 are set in the area A for receiving the power supply 50. The area B is for receiving a data storage device 40 such as a hard disk drive, an optical disk drive or the like.

The retention member 30 is generally L-shaped and may be formed from plastic, composite, metal and the like without departing from the spirit and scope of the present invention. The retention member 30 includes a body 32 and a resilient bending portion 34. A pushing portion 344 is formed on the bending portion 34. A connecting portion 36 connects the body 32 to the bending portion 34. An engaging portion 342 is formed on the bending portion 34 corresponding to the retaining portion 142 of the bracket 10. The engaging portion 342 may be a protrusion formed on the retention member 30 corresponding to a retaining hole 142 formed on the bracket 10. A pair of pivot pins 322 is formed corresponding to the pivot holes 1622 of the bracket 10 respectively on an end of the body 32, for pivoting the retention member 30 on the bracket 10.

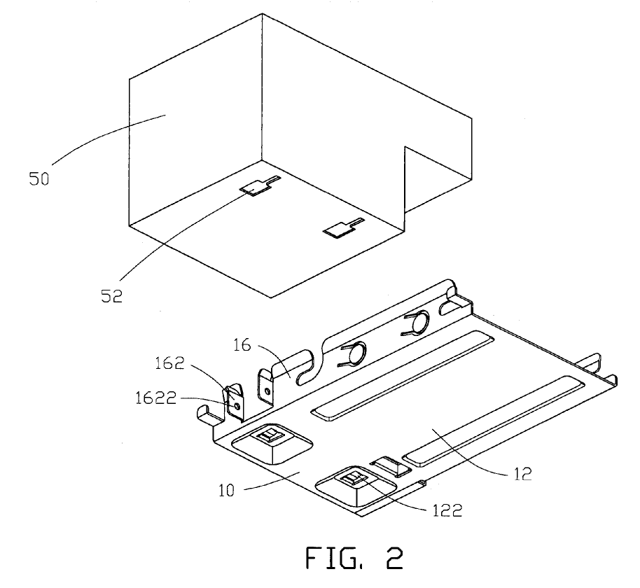

Referring also to FIG. 2, a pair of T-shaped locking holes 52 corresponding to the locking clips 122 of the bracket 10 is defined in a bottom side of the power supply 50. Each locking hole 52 has a wide portion and a narrow portion.

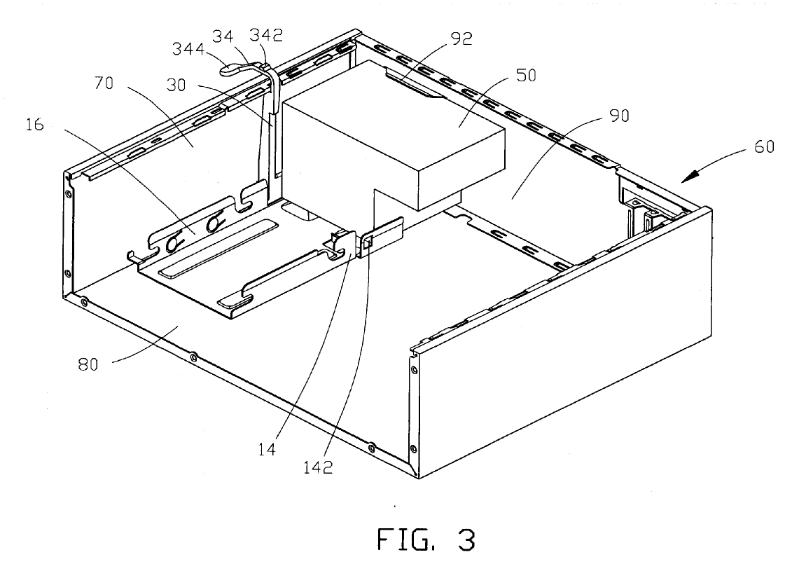

Referring also to FIG. 3, the power supply 50 is secured in a computer chassis 60. The chassis 60 includes a bottom panel 80, a back panel 90 oriented perpendicular to the bottom panel 80, and two opposite side panels 70 extending upwardly and perpendicularly from the bottom panel 80. A top-blocking clip 92 is bent from a top portion of the back panel 90, for stopping the power supply 50 from moving upward. A cutout 72 is defined in a top edge of the side panel 70.

The bracket 10 is mounted to the bottom panel 80 of the chassis 60 by fasteners, such as screws. The retention member 30 is pivotally attached to the bracket 10. The top portion of the retention member 30 is received in the cutout 72 of the side panel 70, when the retention member 30 is located at an unlocked position as shown in FIG. 3.

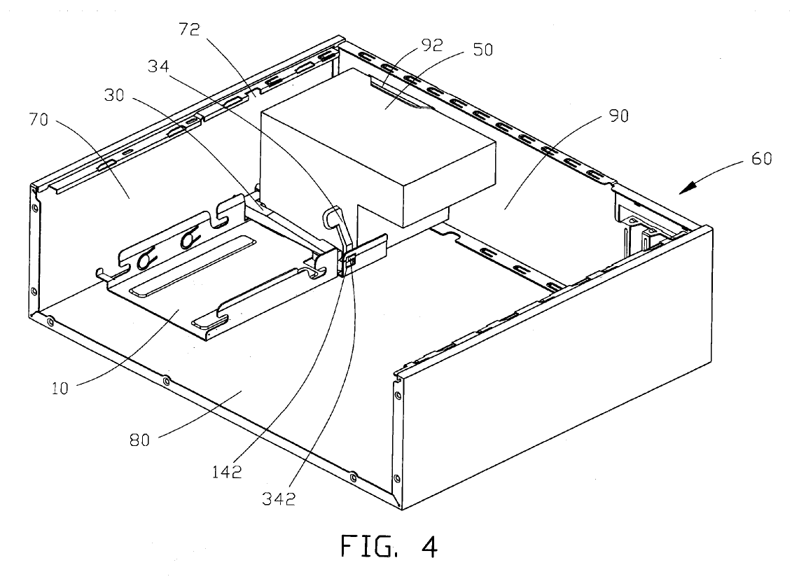

Referring also to FIG. 4, in locking the power supply 50 to the chassis 60, the locking clips 122 of the bracket 10 are aligned with the corresponding locking holes 52 of the power supply 50. The power supply 50 is pushed along the bracket 10 toward the back panel 90 of the chassis 60. Therefore, the locking clips 122 of the bracket 10 are engaged in the corresponding locking holes 52 of the power supply 50, and the power supply 50 is secured under the top-blocking clip 92 of the chassis 60. Then, the power supply 50 is secured in the perpendicular direction to the bottom panel 80 of the chassis 60. The retention member 30 is rotated downwardly from the unlocked position toward the first side wall 14 of the bracket 10. The bending portion 34 is bent toward the second side wall 16 of the bracket 10 when the engaging member 342 of the retention member 30 slidingly abuts against the first side wall 14 of the bracket 10. As the engaging member 342 of the retention member 30 reaches the retaining portion 142 of the bracket, the bending portion 34 deforms back toward its original position, and the engaging member 342 of the retention member 30 snappingly engages with the retaining portion 142 of the bracket 10. This is a locked position where the power supply 50 is secured along a first horizontal direction between the first side wall 14 and the second side wall 16 of the bracket 10, and along a second horizontal direction between the retention member 30 and the back panel 90. In this way, the power supply 50 is secured to the chassis 60.

In unlocking the power supply 50 from the chassis 60, the pushing portion 344 of the retention member 30 is pushed to deform toward the second side wall 16 of the bracket 10, so that the engaging member 342 is disengaged from the retaining portion 142 of the bracket 10. The retention member 30 is rotated from the locked position to an unlocked position. The power supply 50 is moved away from the back panel 90 of the chassis 60, thereby disengaging the locking clips 122 of the bracket 10 from the corresponding locking holes 52 of the power supply 50. Thus, the power supply 50 is unlocked.

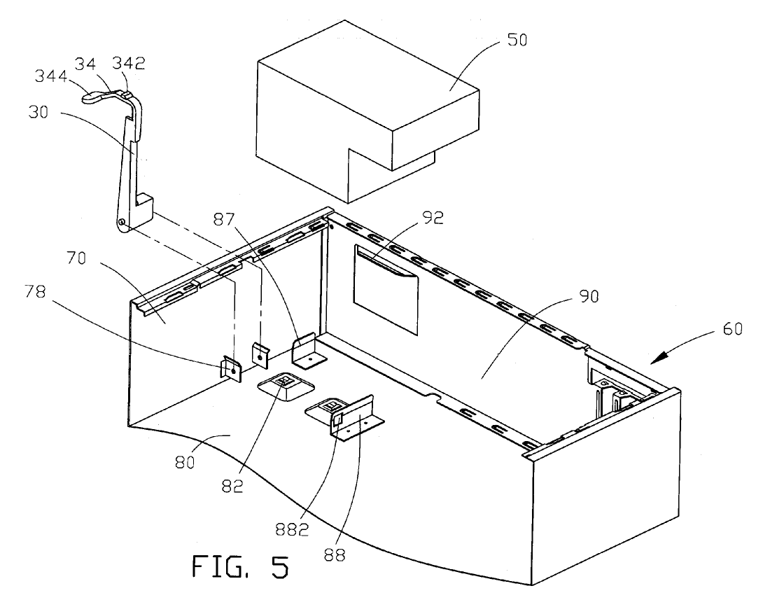

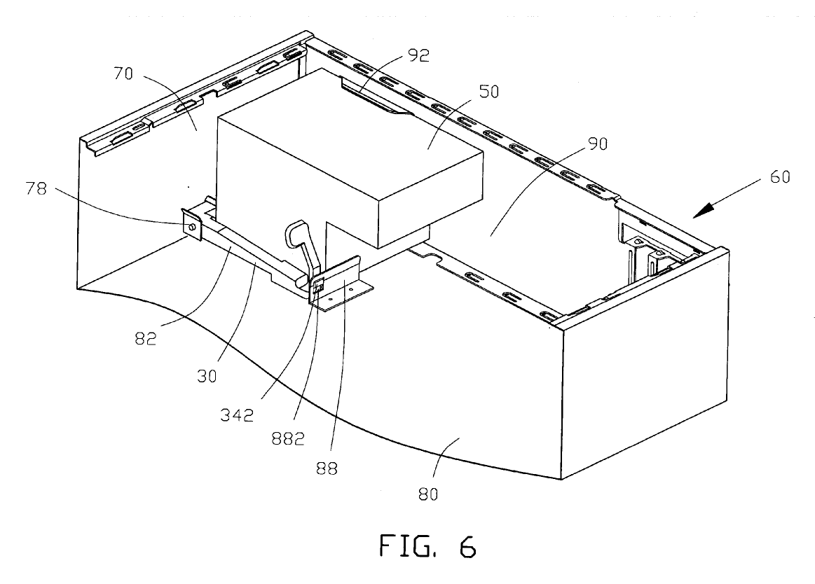

Referring also to FIG. 5 and FIG. 6, an alternative preferred embodiment of the present invention is disclosed. A pair of locking clips 82 is formed on the bottom panel 80. A pair of side walls 87, 88 is formed on the bottom panel 80 for retaining the power supply 50 on the chassis 60. The side wall 88 defines a retaining hole 882 for engagingly receiving the engaging portion 342 of the retention member 30, thereby locking the retention member 30 in a locked position. A pair of retaining clips 78 is formed on the side panel 70 of the chassis 60 for pivoting the retention member 30. When the retention member 30 is locked to the side wall 88 of the chassis 60, the power supply 50 is secured to the chassis 60.

The engaging portion 342 of the retention member 34 and the retaining portion 142 of the bracket 10 or the chassis 60 in the preferred embodiments can be interchanged, for realizing the same function.

It is to be understood, however, that even though numerous characteristics and advantages have been set forth in the foregoing description of a preferred embodiments, together with details of the structure and function of the preferred embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A mounting apparatus for securing an electronic device to an electronic enclosure, comprising:
a chassis comprising a bottom panel;
a bracket secured on the bottom panel, the bracket comprising a first side wall and a second side wall for cooperatively sandwiching the electronic device therebetween; and
a retention member pivotably attached to the chassis and engaged with one of the first and second side walls to lock the electronic device between the first and second side walls.

2. The mounting apparatus as described in claim 1, wherein a pair of pivot pins is formed on the retention member, and one of the first and second side walls defines a pair of pivot holes for pivotably attaching the retention member.

3. The mounting apparatus as described in claim 1, wherein the electronic device defines a locking hole in a bottom surface, and a locking clip is formed on the bracket for engaging with the locking hole, thereby securing the electronic device in a perpendicular direction of the chassis.

4. The mounting apparatus as described in claim 1, wherein a retaining portion is formed on the other one of the first and second side walls of the bracket, and an engaging portion corresponding to the retaining portion is formed on the retention member.

5. The mounting apparatus as described in claim 4, wherein the engaging portion of the retention member is a protrusion, and the retaining portion of the bracket is a retaining hole.

6. The mounting apparatus as described in claim 1, wherein the chassis further comprises a side panel, a cutout is defined in a top edge of the side panel, and the cutout receives the retention member therein, when the retention member is rotated to a unlocked position.

7. The mounting apparatus as described in claim 1, wherein the chassis further comprises a back panel perpendicular to the bottom panel, the electronic device is sandwiched between the back panel and the retention member.

8. The mounting apparatus as described in claim 1, wherein a resilient bending portion is formed on the retention member, and a pushing portion is formed on the bending portion for operation of the pushing retention member.

9. A mounting apparatus for an electronic device, comprising:
a chassis comprising a bottom panel, and a back panel formed on the bottom panel; and
a retention member attached to the chassis and being pivotable between a locked position in which the electronic device is sandwiched between the back panel and the retention member and an unlocked position in which the electronic device is released.

10. The mounting apparatus as described in claim 9, wherein the electronic device defines a locking hole in a bottom surface, and a locking clip is formed on the chassis for engaging with the locking hole, thereby securing the electronic device in a perpendicular direction of the chassis.

11. The mounting apparatus as described in claim 9, wherein a pair of side wall is formed on the bottom panel of the chassis for cooperatively sandwiching the electronic device therebetween.

12. The mounting apparatus as described in claim 11, wherein a pair of pivot pins is formed on the retention member, and one of the side walls defines a pair of pivot holes for pivotably attaching the retention member.

13. The mounting apparatus as described in claim 12, wherein a retaining portion is formed on the other one of the side walls, and an engaging portion corresponding to the retaining portion is formed on the retention member.

14. The mounting apparatus as described in claim 13, wherein the engaging portion of the retention member is a protrusion, and the retaining portion of the bracket is a retaining hole.

15. The mounting apparatus as described in claim 9, wherein the chassis further comprises a side panel, a cutout is defined in a top edge of the side panel, and the cutout can receive the retention member, when the retention member is rotated to a unlocked position.

16. The electronic assembly as described in claim 9, wherein the retention member is L-shaped.

17. The electronic assembly as described in claim 9, wherein a resilient bending portion is formed on the retention member, and a pushing portion is formed on the bending portion.

18. A mounting assembly comprising:
a chassis comprising a first wall portion and a second wall portion;
an electronic device sandwiched between the first and second wall portions along a first direction;
a retention member attached to the chassis, and being pivotable about an axis along a second direction perpendicular to the first direction between a locked position where the electronic device is locked along the second direction, and an unlocked position where the electronic device is released along the second direction.

19. The mounting assembly as described in claim 18, wherein the retention member is pivoted to one of the first and second wall portions, and engaged with the other of the first and second wall portions in the locked position.

20. The mounting assembly as described in claim 18, wherein a bottom wall is connected between the first and second wall portions to form a bracket, and the bracket defines a first area receiving the electronic device, and a second area configured for receiving a data storage device.
